(19) United States
(12) Patent Application Publication
(10) Pub. No.: US 2010/0259941 A1
(43) Pub. Date: Oct. 14, 2010

(54) Covering for a lighting device

(75) Inventor: Tim Brennan, Las Vegas, NV (US)

Correspondence Address: Law Office of Scott C Harris Inc, PO Box 1389, Rancho Santa Fe, CA, 92067, US

(73) Assignee: PRODUCTION RESOURCE GROUP L.L.C, New Windsor, NY (US)

(21) Appl. No.: 12/722,224

(22) Filed: Mar. 11, 2010

Related U.S. Application Data
(60) Provisional application No. 61/159,766, filed on Mar. 12, 2009.

(51) Int. Cl. F21V 15/00; H05K 5/00; B23P 11/00

(52) U.S. Cl. 362/362; 174/50; 29/428

(57) ABSTRACT

An electronic component, e.g., a stage light, covered with a vehicle wrap material, to change the color.

This application claims priority from Provisional application No. 61/159,766, filed Mar. 12, 2009, the entire contents of which are herewith incorporated by reference.

### BACKGROUND

Marketing wrap has been used for covering certain items to create advertising using the surfaces of those items. When used for covering automobiles, the product is often called vehicle wrap, and allows a special kind of advertising. Marketing wrap and vehicle wrap is typically made of vinyl on which printing has been carried out. The wrap can cover the whole or only part of the surface. The vinyl can be put over the windows and doors and seen through.

Marketing wrap has been used on buildings and the like to form billboards using the surface of a building.

### SUMMARY

The present application describes a technique of using vinyl wrap as covering over electronic devices. More specifically, this describes using marketing wrap over stage luminaires.

### BRIEF DESCRIPTION OF THE DRAWINGS

In the Drawings:

FIG. 1 shows a moving light covered with a vinyl wrap.

### DETAILED DESCRIPTION

Stage lighting systems often operate with a number of stage lights being located in specific locations, and the lights collectively shining at a stage or other target. Each of the stage lights produce large amounts of light, e.g., more than 1000 lumens, and/or with a bulb, or “lamp”, that has an output that is greater than 500 watts. The producing of the light also creates a reasonably large amount of heat.

Stage lights are often made with a colored housing. The exterior color of the stage lights can be changed by painting the outside of the lights or by obtaining color versions of the light housing. Both are expensive and frequently the quality of the finished product is unsatisfactory, because it is difficult to get the retrofit to look “new”. Also, each of these techniques typically requires at least a partial disassembly of the luminaire.

Based on recognizing this problem, the inventor conceived of colored vinyl, such as vehicle wrap, to re-color and change the look of, the outside of a light. I realized that no one had used marketing wrap on non washable surfaces. One problem is that the wraps use glue, and many of the glues leave sticky residue on the outside of the previously attached-to device.

On parts like a car or a building, that sticky residue can be removed. However, it can be more difficult to remove the sticky residue from an electronic device, like a light, that cannot be washed.

Also, the outside surface of a luminaire often gets hot because of the operation of the lamp inside the luminaire. We believe that many were concerned that the vinyl material would not stand up to this heat.

I found that some wrap glues left less residue than others. The 3M wrap product was particularly good in this regard. In general, the less expensive products leave residue from the glue, and do not peel off as well. However, a low residue product can be used even on these objects which cannot be washed.

I found that quality marketing wrap could be used on the outside of a moving stage light. Contrary to what one would normally expect, the residue left by the sticky side of the marketing wrap does not prevent further use of the light or endanger the warranty.

With a quality wrap, we found that the fixture could be we found that the fixture could be run for many hours. When we then took the marketing wrap off the lights, and found that there was little or no residue on the outside of the lights.

The marketing wrap used can be 2 mm thick, cast vinyl wrap. Certain wraps, such as 3M Controltac Wrap Film IJ380Cv3, with Comply™ v3 adhesive is made for vehicles with many corners and curves, and may be ideal for luminaires. However, other vinyl wraps can be used, such as 3M™ Scotchcal™ Gloss, or others.

We believe that wraps of this kind can be used on any electronic device. For example, the kind of wraps may be used on any product where painting of the product is difficult, where the product should not be wet, and where the product may become heated during normal operation.

The marketing wrap covers some fixtures better than others. Generally, fixtures with defined lines and edges worked better than others. Fixtures from Martin professional, Clay Paky, and the like have better defined lines and edges, and worked better for this product. However, other fixtures such as Vari Lite fixtures, even with the rounded corners and blended body parts, can also be covered successfully.

Another unexpected result was the cost difference. Marketing wrap to cover a fixture will might cost $150. Painting the same fixture might be almost 10 times as much, for example a cost for painting the fixture might be $1250.

The above describes using marketing wrap for changing the color of a fixture, e g. from black to white. However, this same technique can be used for making patterns of any desired size or shape on the outside of the fixture.

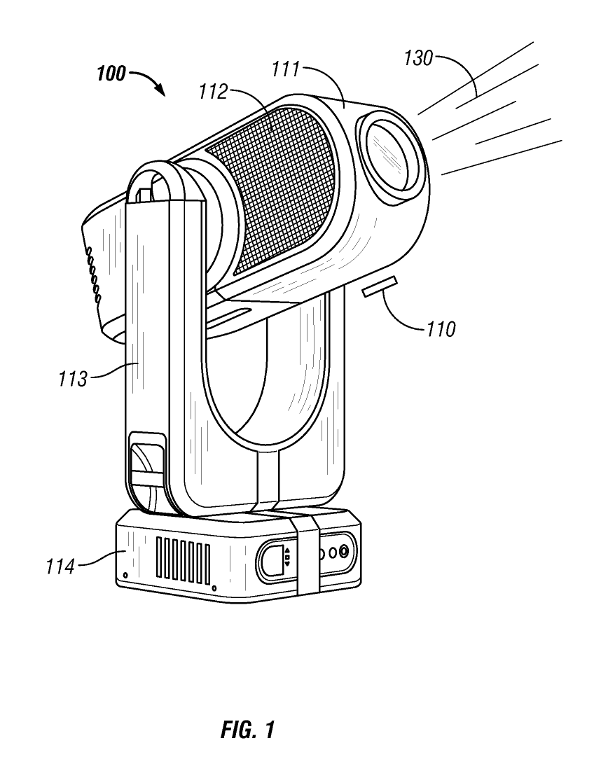

In one embodiment, a luminaire 100 in FIG. 1 was wrapped with marketing wrap 110, causing the eventual wrapped light to have some or all of all of its exposed surfaces to be seen as white. When the light is “wrapped” in this way, people who look at the light see the vinyl, rather than seeing the color of the light housing.

In an embodiment, the vinyl wrap may be any of a number of commercially available vinyl wrap materials. The wrap materials can be applied using the following techniques.

First, the surface of the luminaire housing is cleaned. This can use a damp cloth, or a cloth with a solvent. Lint free towels may be used in order to minimize the amount of residue left by the cleaning. One simple way to carry out the cleaning may simply be to use isopropyl alcohol for example. It is important to remove the dirt from the crevices so that the vinyl material sticks properly. Next, the vinyl material is placed over the different surfaces that are to be covered, and roughly cut. The vinyl material may be laid out and positioned on the surfaces with tape.

Next, in an area that is maintained at a temperature between 70 and 80° F., the vinyl is glued to the desired surfaces. A heat gun can be used to slightly shrink the vinyl as necessary, or alternatively, the heat of the operation of the electronic device itself may eventually may be used to cause the shrinkage.

According to an embodiment, the entire operation can be carried out without any disassembly of the luminaire. According to another embodiment, certain places on the luminaire, such as the panels that are normally removed to obtain access to electronics and lighting, maybe removed for the purpose of applying the vinyl coating.

Another embodiment may use one or more of the vinyl wrap primers on the surface. The primer might be used only on some parts, e.g., it may be used only on the curved portions. For example, primer may be used on the curved portions in order to obtain a better adherence to those curved portions. The primer may add another layer of material that may be more difficult to remove.

Importantly, while many of the wraps are rated for ambient temperatures up to 100° F., it was found in practice that these wraps would work fine on the surfaces of luminaires, where those surfaces often reach much higher temperatures.

Although only a few embodiments have been disclosed in detail above, other embodiments are possible and the inventors intend these to be encompassed within this specification. The specification describes specific examples to accomplish a more general goal that may be accomplished in another way. This disclosure is intended to be exemplary, and the claims are intended to cover any modification or alternative which might be predictable to a person having ordinary skill in the art. For example, other forms and materials of wraps can be used. While the wraps are described as being used on luminaires, they can alternatively be used on other devices that are electronically controlled. Other embodiments contemplate using other colors of vinyl or other patterns.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

Any of the steps carried out herein can be done using a computer.

Also, the inventors intend that only those claims which use the words “means for” are intended to be interpreted under 35 USC 112, sixth paragraph. Moreover, no limitations from the specification are intended to be read into any claims, unless those limitations are expressly included in the claims.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A electronic device, comprising:
a first part, operated by electricity, that creates heat when it consumes electricity, and where said first part is not intended to be wet;
a housing, holding said first part; and
a colored vinyl wrap which is glued to said housing.

2. A device as in claim 1, wherein said electronic device is a stage lighting luminaire that has produces the light output of at least 1000 lumen.

3. An electronic device as in claim 2, wherein said vinyl wrap is vehicle wrap.

4. An electronic device as in claim 3, further comprising low residual adhesive which glues said vinyl wrap to said housing.

5. A method of changing a color of a housing of an electronic device, comprising:
changing a color of a housing of the electronic device by attaching a vinyl wrap to at least one surface of the housing of the electronic device where the vinyl wrap has a different color than an original surface of the housing of the electronic device, and where the vinyl wrap is attached over the at least one surface of the electronic device; and
at a first time, operating the electronic device in a way that creates heat with the vinyl wrap covering the at least one surface.

6. A method as in claim 5, wherein said attaching comprises using a glue.

7. A method as in claim 6 wherein said attaching comprises applying a primer on at least some areas of the at least one surface and not applying the primer on other areas of the at least one surface.

8. A method as in claim 7 wherein said attaching further comprises using heat from said operating of the electronic device to shrink the vinyl wrap.

9. A method as in claim 5 further comprising removing the vinyl wrap and operating the electronic device without the vinyl wrap at a subsequent time after said first time.

10. A method as in claim 5, wherein said electronic device is a light having an output of greater than 1000 lumens.

11. An electronic device, comprising:
at least one electronic component;
a connection for said electronic component, which when powered causes said electronic component to operate and to create heat;
a housing for said at least one electronic component, which is heated by said operation; and
a vinyl covering on said housing, attached to said housing by a glue part, wherein said vinyl covering is a different color then the color of the housing, and where the vinyl covering covers at least part of the housing.

12. An electronic device as in claim 11, wherein said electronic component is a light having an output of greater than 1000 lumens
